(19) United States
(12) Patent Application Publication
(10) Pub. No.: US 2020/0028005 A1
(43) Pub. Date: Jan. 23, 2020

(54) Bifacial Solar Modules Incorporating Effectively Transparent Contacts

(71) Applicant: California Institute of Technology, Pasadena, CA (US)

(72) Inventors: Rebecca Saive, Enschede (NL); Thomas Russell, Pasadena, CA (US); Harry A. Atwater, South Pasadena, CA (US)

(73) Assignee: California Institute of Technology, Pasadena, CA (US)

(21) Appl. No.: 16/243,930

(22) Filed: Jan. 9, 2019

Related U.S. Application Data
(60) Provisional application No. 62/615,075, filed on Jan. 9, 2018.

(51) Int. Cl. H01L 31/0224; H01L 31/02

(52) U.S. Cl. CPC H01L 31/022433; H01L 31/0747; H01L 31/022466; H01L 31/0201

(57) ABSTRACT

Bifacial solar cells have been gaining momentum due to their promise of reducing the price of photovoltaic generated electricity by increasing power output. In addition to front side illumination, bifacial solar cells can also accept photons incident on the rear side. In many embodiments, increased power output values of up to and around 50% can be achieved. In some circumstances, other values can be achieved. For example, ˜40-70% under cloudy conditions and between ˜13-35% under sunny conditions, depending on the height of the ground clearance, can be achieved. Other factors such as but not limited to the (spectral) albedo of the surroundings as well as the geometry in which the cells are mounted can strongly influence the power output. As can readily be appreciated, the exact amount of increased power output can vary widely depending on the configuration and operating conditions of the bifacial solar cell.

### CROSS-REFERENCE TO RELATED APPLICATIONS

The current application claims the benefit of and priority under 35 U.S.C. § 119(e) to U.S. Provisional Patent Application No. 62/615,075 entitled “Enhancing the Power Output of Bifacial Solar Modules by Applying Effectively Transparent Contacts with Light Trapping,” filed Jan. 9, 2018. The disclosure of U.S. Provisional Patent Application No. 62/615,075 is hereby incorporated by reference in its entirety for all purposes.

### STATEMENT REGARDING FEDERALLY SPONSORED RESEARCH OR DEVELOPMENT

This invention was made with government support under Grant No. DE-EE0004946 awarded by the Department of Energy and under Grant No. EEC1041895 awarded by the National Science Foundation. The government has certain rights in the invention.

### FIELD OF THE INVENTION

The present invention generally relates to solar cells and, more specifically, bifacial solar cells.

### BACKGROUND

Photovoltaics refer to a class of methods for converting light into electricity using the photovoltaic effect. Due to technological advances in recent years, photovoltaics are becoming a more viable, carbon-free source of electricity generation. A photovoltaic system typically employs an array of solar cells to generate electrical power. Solar cells can be made of a variety of semiconductors, typically a silicon based structure, acting as a substrate and can include front and rear contacts that are used to conduct current out of the solar cell. The conversion process involves the absorption of light rays by what can be referred to as the active region of the solar cell, which can excite electrons in the substrate into a higher state of energy. The excitation allows the electrons to move as an electric current that can then be extracted to an external circuit and stored.

### SUMMARY OF THE INVENTION

One embodiment includes an optoelectronic device including a bifacial solar cell including a photoabsorbing material having first and second surfaces, wherein the first and second surfaces are configured to accept incoming external photons, and a plurality of effectively transparent contacts disposed on the first and second surfaces, wherein the plurality of effectively transparent contacts includes three-dimensional structures, each three-dimensional structure having at least one surface configured to redirect incident photons towards either the photoabsorbing material, and the plurality of effectively transparent contacts covers at least 5% of the first surface from external photons.

In another embodiment, wherein the photoabsorbing material includes a material that is one of a III-V material, GaAs, CdTe, GICS, perovskite, and silicon.

In a further embodiment, the optoelectronic device further includes a plurality of existing metallic contacts on the first surface, wherein at least a portion of the plurality of effectively transparent contacts are disposed on top of the existing metallic contacts.

In still another embodiment, wherein the plurality of effectively transparent contacts covers at least 10% of the first surface.

In a still further embodiment, wherein the plurality of effectively transparent contacts covers about 20% of the first surface and less than 50% of the second surface.

In yet another embodiment, wherein the plurality of effectively transparent contacts covers between 5% to 50% of the first photoabsorbing surface and between 5% to 50% of the second photoabsorbing surface.

In a yet further embodiment, wherein the plurality of effectively transparent contact covers the same percentage of the first surface and the second surface.

In another additional embodiment, wherein the plurality of effectively transparent contact covers more of the first surface than the second surface.

In a further additional embodiment, wherein the first photoabsorbing surface contains only one busbar.

In another embodiment again, wherein the plurality of effectively transparent contacts includes triangular contacts having aspect ratios of higher than 2:1.

In a further embodiment again, wherein the triangular contacts are each approximately 10 micrometers wide and approximately 30 micrometers high.

In still yet another embodiment, wherein the plurality of effectively transparent contacts is configured to have an effective transparency of greater than 99%.

In a still yet further embodiment, the optoelectronic device further includes a polymer layer, wherein the polymer layer embeds the plurality of transparent contacts.

In still another additional embodiment, wherein the polymer layer includes a material selected from the group consisting of: ethylene-vinyl acetate, polydimethylsiloxane, polyurethane, and polymethylmethacrylate.

In a still further additional embodiment, wherein the polymer layer has a thickness of less than 500 μm.

In still another embodiment again, the optoelectronic device further includes a transparent conductive oxide layer having a thickness of less than 200 nm, wherein the transparent conductive oxide layer is in contact with the photoabsorbing layer.

In a still further embodiment again, wherein the transparent conductive oxide layer has a thickness of less than 100 nm.

In yet another additional embodiment, wherein the transparent conductive oxide layer includes a material that is one of indium tin oxide and fluorine doped tin oxide.

In a yet further additional embodiment, wherein at least one of the effectively transparent contact includes silver nanoparticle ink.

In yet another embodiment again, wherein at least one of the effectively transparent contact includes a triangular core in contact with at least two reflective surfaces.

Additional embodiments and features are set forth in part in the description that follows, and in part will become apparent to those skilled in the art upon examination of the specification or may be learned by the practice of the invention. A further understanding of the nature and advantages of the present invention may be realized by reference to the remaining portions of the specification and the drawings, which forms a part of this disclosure.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The description will be more fully understood with reference to the following figures and data graphs, which are presented as exemplary embodiments of the invention and should not be construed as a complete recitation of the scope of the invention.

FIG. 1 conceptually illustrates schematically a bifacial solar cell with ETCs on both the front and back sides in accordance with an embodiment of the invention.

FIG. 2 conceptually illustrates a profile view of a section of a solar cell with an ETC on top of a standard planar contact in accordance with an embodiment of the invention.

FIG. 3A conceptually illustrates a schematic of a layer structure of a simulated silicon heterojunction solar cell in accordance with an embodiment of the invention.

FIG. 3B conceptually illustrates a busbar structure of a simulated silicon heterojunction solar cell in accordance with an embodiment of the invention.

FIG. 3C conceptually illustrates a double screen-printed contact structure of a simulated silicon heterojunction solar cell in accordance with an embodiment of the invention.

FIG. 3D conceptually illustrates an effectively transparent contact structure of a simulated silicon heterojunction solar cell in accordance with an embodiment of the invention.

FIG. 4 shows a graph of the corresponding EQE depending on wavelength for several module configurations in accordance with various embodiments of the invention.

FIG. 5 shows a chart of the light trapping and shading loss (without busbars) of multiple coverage scenarios of various contact design configurations in accordance with various embodiments of the invention.

FIG. 6 shows a graph of the generated current density for rear side illumination depending on the ETC rear coverage and on the angle of incidence for an ETC front coverage of 20% in accordance with various embodiments of the invention.

FIGS. 7A and 7B conceptually illustrate the relative current density for different rear intensities and different contact configurations compared to a monofacial cell and a bifacial cell with the reference screen-printed contacts in accordance with various embodiments of the invention.

FIG. 8A shows a graph plotting the series resistance against varying coverages for different grid configurations in accordance with various embodiments of the invention.

FIG. 8B shows a graph illustrating the silver consumption of different grid configurations in accordance with various embodiments of the invention.

### DETAILED DESCRIPTION

Turning now to the drawings, bifacial cells incorporating effectively transparent contacts are illustrated. Bifacial solar cells have been gaining momentum due to their promise of reducing the price of photovoltaic (“PV”) generated electricity by increasing power output. In addition to front side illumination, bifacial solar cells can also accept photons incident on the rear side. In many embodiments, increased power output values of up to and around 50% can be achieved. In some circumstances, other values can be achieved. For example, ˜40-70% under cloudy conditions and between ˜13-35% under sunny conditions, depending on the height of the ground clearance, can be achieved. Other factors such as but not limited to the (spectral) albedo of the surroundings as well as the geometry in which the cells are mounted can strongly influence the power output. As can readily be appreciated, the exact amount of increased power output can vary widely depending on the configuration and operating conditions of the bifacial solar cell.

Increased photon acceptance translates into increased power output if charge carriers can be extracted and transported efficiently. In silicon solar cells, which present more than 90% of the PV market and a majority of, if not all, commercial bifacial technology, charge transport is typically achieved through screen-printed silver contacts. Due to the shading of these metal contacts, between ˜5% and ˜10% of the incident light is typically lost. One approach for an alternative contact design includes the use of effectively transparent contacts (“ETCs”) that are capable of mitigating these shading losses without sacrificing the charge conduction. Note, however, that interdigitated back contacts (“IBCs”) cannot be applied to bifacial solar modules and, therefore, to date ETCs constitute the only solar cell contact technology that can achieve shading loss of less than 0.1% and that is suitable for bifacial solar cells. As such, many embodiments of the invention are directed towards bifacial solar cells that incorporate effectively transparent contacts. Further sections below also discuss computationally how ETCs can enhance the absorption of exemplary bifacial silicon heterojunction solar modules through the efficient redirecting of light into the solar cell and by trapping light within the crystalline silicon. Computational optical simulations of different front and rear illumination scenarios can be performed. The grid resistance of the investigated contact layouts can be calculated. Additionally, by using ETCs, the amount of busbars can be reduced compared to a standard bifacial solar cell contact grid layout. This leads to a decrease in silver consumption as well as to an additional advantage for photon absorption.

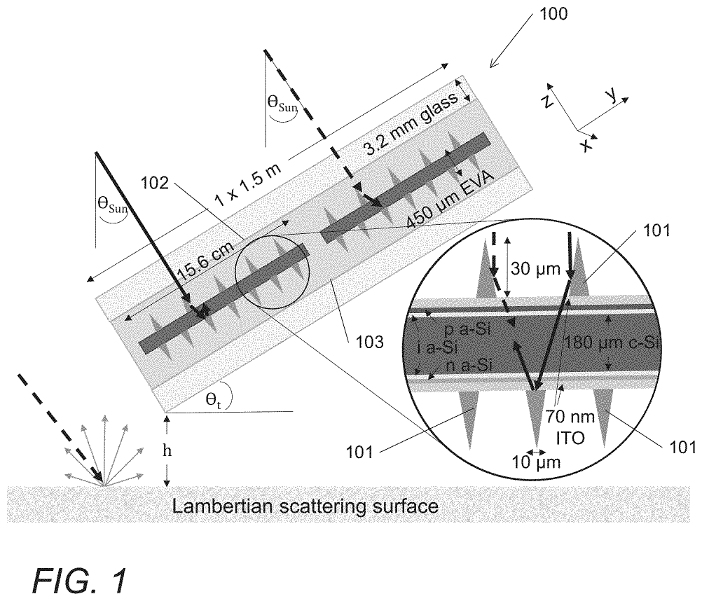

Bifacial solar cells incorporating ETCs can be implemented in various ways to allow for increased power output through their bifacial properties in conjunction with their ability to reduce or eliminate shading losses through the use of ETCs. For example, in some embodiments, densely spaced ETCs are implemented and are able to enhance the light trapping in thin silicon solar cells. Other ETC designs and configurations can be considered for various reasons including but not limited to the intended operating environment. FIG. 1 conceptually illustrates schematically a bifacial solar cell 100 with ETCs 101 on both the front and back sides in accordance with an embodiment of the invention. As shown, the front side 102 experiences mostly direct illumination from the sun while the rear side 103 is exposed to diffused light from the back reflection of the surroundings. With ETCs, photons incident on a metal contact can be efficiently redirected to the active area due to the triangular geometry of ETCs (FIG. 1: dashed arrows). Low energy photons that are not absorbed during the first pass can be reflected back at the bottom of the ETCs, leading to light trapping (FIG. 1: solid arrows). ETCs, solar cells, bifacial configurations, and modeling simulations are discussed below in further detail.

### Effective Transparency

In conventional solar cells with planar contacts, a non-negligible fraction of the incoming solar power is immediately lost either through absorption or through reflection. In such solar cells, only photons incident on the active photoabsorbing surface are capable of conversion to an electric current. Approaches for mitigating solar cell front contact losses can include using less absorbing transparent conductive oxides, or less reflective metal contacts. Achieving improved transparency using these approaches typically results in reduced conductivity, which in turn leads to series resistance electrical losses in the solar cell.

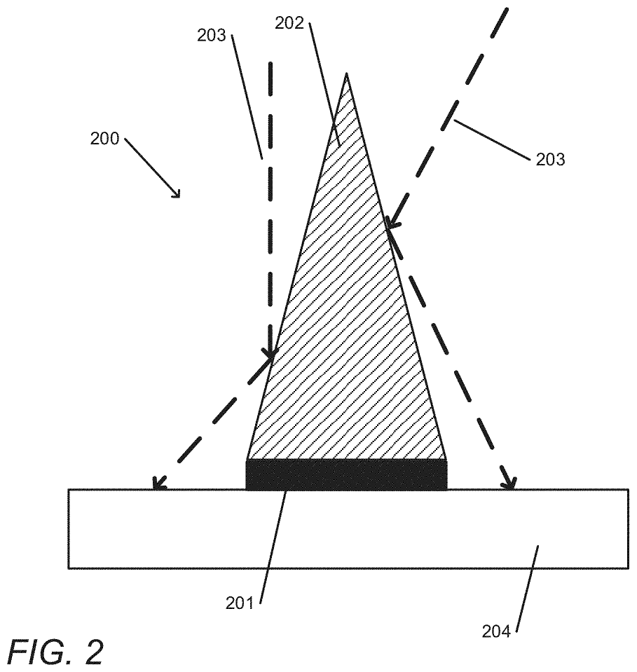

Solar cells in accordance with many embodiments of the invention incorporate effectively transparent contacts. The contacts are effectively transparent in the sense that they are formed with three-dimensional (“3D”) shapes that reflect or redirect incident photons onto the active photoabsorbing surface of the solar cell. ETCs can be implemented to overcome shadowing losses and parasitic absorption without significantly reducing the conductivity of the contacts relative to conventional planar grid fingers. A solar cell incorporating ETCs can be fabricated with the ETCs either on top of existing contacts or on the photoabsorbing surface. FIG. 2 conceptually illustrates a profile view of a section of a solar cell with an ETC on top of a standard planar contact in accordance with an embodiment of the invention. As shown, the solar cell 200 includes a planar contact 201 a triangular cross-section ETC 202 that is designed to redirect incident light 203 to an active photoabsorbing surface 204 of the solar cell. In this way, the triangular cross-section ETC can perform as effectively transparent.

Although triangular cross-section contacts are described above with reference to the solar cell illustrated in FIG. 2, any of a variety of ETCs having profiles that redirect incident radiation in a manner appropriate to the requirements of specific solar cell applications can be utilized in accordance with various embodiments of the invention. In many embodiments, ETCs are implemented on top of the photoabsorbing surface of the solar without an intermediary planar contact. ETC designs and implementations are generally discussed in U.S. patent application Ser. No. 15/144,807, entitled “Solar Cells and Methods of Manufacturing Solar Cells Incorporating Effectively Transparent 3D Contacts,” and U.S. patent application Ser. No. 15/453,867, entitled “Encapsulated Solar Cells that Incorporate Structures that Totally Internally Reflect Light Away from Front Contacts and Related Manufacturing Methods.” The disclosures of U.S. patent application Ser. Nos. 15/144,807 and 15/453,867 are hereby incorporated by reference in their entireties.

### Effectively Transparent Contact Designs

Effectively transparent contacts in accordance with various embodiments of the invention can be fabricated in a variety of shapes, sizes, and patterns. In certain embodiments, the triangular cross-sections can be equilateral triangles (having a base that is wider than the height of the triangle), isosceles triangles, right angle triangles, scalene triangles, or obtuse triangles. In various embodiments, the triangles are constructed to have heights that are greater than the base width of the triangles (i.e. the surface closest to the photoabsorbing surface has a width that is less than the height to which the triangle extends above the photoabsorbing surface). In many embodiments, a surface of the ETC has a parabolic shape. In other embodiments, any of a variety of surface shapes can be utilized that redirect light incident on the contacts onto the photoabsorbing surfaces of the solar cells.

ETCs can be fabricated with widely varying dimensions that can depend on the specific requirements of a given application. In many embodiments, the ETCs have triangular cross-sections with a height-to-base ratio of at least 2:1, where the base side sits parallel with respect to the surface of the solar cell. In further embodiments, the ETCs have a height-to-base ratio of at least 3:1. For example, in some embodiments, the ETCs are fabricated to be approximately 10 micrometers wide and approximately 30 micrometers high. As can readily be appreciated, the dimensions of the ETCs to be fabricated can depend on the specific requirements of a given application. Different fabrication processes can allow for different height-to-base ratios. Such differences in cross-sectional shapes and sizes can influence the effective transparency of the ETCs. Additionally, processes in accordance with various embodiments of the invention allow for the fabrication of ETCs having line widths of less than 10 micrometers.

A wide variety of ETC patterns can be implemented in accordance with various embodiments of the invention. In many embodiments, the ETCs are fabricated in a pattern that matches the pattern of existing contacts on a solar cell. In some embodiments, the ETCs are fabricated on the contact fingers of a solar cell in a parallel configuration of triangular prisms. ETCs can also be formed to have a tapered width and/or tapered height. By reducing the channel size, capillary forces can be enhanced. As will be discussed in the sections below, capillary forces can be used to aid the filling process in the fabrication of ETCs. In addition to enhancing the capillary forces, material use can be reduced. In a number of embodiments, an ETC having a triangular cross section is formed on the busbar of a solar cell. Busbar ETCs formed in accordance with various embodiments of the invention can have feature sizes of a few micrometers. Multiple triangular shaped busbars can be used to provide sufficient sheet resistance. In several embodiments, the sizes of the busbars are reduced to mesoscale in order to provide sufficient optical transparency and redirection of incoming light.

Although specific contact designs are discussed above, any of a variety of different contact shapes and patterns can be used to facilitate the redirection of incoming light and/or enhance the filling mechanisms, such as but not limited to increasing the capillary forces.

### Fabrication Processes for Incorporating Effectively Transparent Contacts

Solar cells incorporating ETCs can be fabricated in many different ways in accordance with various embodiments of the invention. A solar cell can incorporate ETCs by either fabricating the ETCs on top of existing planar contacts or on top of the photoabsorbing surface of a solar cell. Many fabrication processes include the use of a mold stamp having grooves with cross-sections corresponding to the desired ETC structures to be fabricated. Mold stamps in accordance with various embodiments of the invention can be made of various materials, such as but not limited to polydimethylsiloxane (“PDMS”), polymethyl methacrylate (“PMMA”), ethylene-vinyl acetate (“EVA”), and other suitable polymers. In many embodiments, the mold stamp is formed as a copy of a master mold. The master mold can be formed using various microfabrication techniques. In some embodiments, additive manufacturing techniques are utilized at the micro-scale to form the desired structures on the master mold. In other embodiments, selective etching techniques, such as but not limited to dry etching, can be used to form the master mold. A mold stamp can then be formed as a relief from the master mold using standard molding techniques.

In embodiments where the ETCs are fabricated on top of existing contacts, the fabrication process is introduced as a secondary metallization step in the overall fabrication process of the manufacturing of the solar cell. The secondary step can be integrated with existing processes for the manufacturing of solar cells. In a conventional solar cell, metal contacts can form an ohmic contact with the semiconductor metal below the contact. Once these contacts are formed, the secondary metallization step can be introduced to integrate aligned ETCs on top of the existing metal contacts to mitigate shading losses and improve electrical conductivity.

### Optical Modeling of Bifacial Solar Cells Incorporating ETCs

Optical modeling can be performed on various bifacial solar cells incorporating effectively transparent contacts in accordance with various embodiments of the invention. Although the discussions below are in regards to heterojunction solar cells, bifacial solar cells incorporating effectively transparent contacts can be implemented in a variety of other types of cells. Depending on the specific configuration and use case, certain assumptions can be made. For example, in modeling the optical properties of a bifacial solar cell similar to the one depicted in FIG. 1, it can be assumed that the bifacial module (under normal operating conditions) accepts mostly direct irradiation at the front and mostly diffused light at the rear. Under clear sky conditions, this can be a realistic assumption. Under cloudy conditions, there can also be a significant portion of diffused light incident on the front side. In many cases, modeling can show that the optimal grid configuration for direct or diffuse front side illumination is similar. Considering the clear sky case, it can be assumed that the total irradiance (Iₜₒₜₐₗ) incident is given by the sum of front (I_{front}) and rear (Iᵣₑₐᵣ) illumination:

Iₜₒₜₐₗ(λ)=I_{front}(λ)+Iᵣₑₐᵣ(λ)

On the front, AM 1.5G (ASTM G-173-03) irradiation can be assumed:

I_{front}(λ)=AM1.5G(λ)

On the rear side, the irradiation can depend on geometric factors—which can be summarized in a constant C (0≤C≤1), on the wavelength (λ) dependent albedo R_{A}(λ), and on the angle of incidence. The angle parallel to the grid fingers can be defined as the x-axis, and the angle perpendicular to the grid fingers can be defined as the y-axis. The wavelength and angle dependent rear illumination can be given by:

Iᵣₑₐᵣ(λ,x,y)=AM1.5G(λ)·C·R_{A}(λ)·cos(x,y)

The short circuit density generated by a photon with wavelength λ(j(λ)) can be determined if the external quantum efficiency (EQE(λ)) is known and the internal quantum efficiency (“IQE”) is assumed to be one. For the front, the following expression can be obtained:

j_{front}(λ)=EQE_{front}(λ)·AM1.5G(λ)

For the rear side, the following expression can be obtained:

jᵣₑₐᵣ(λ)=EQEᵣₑₐᵣ(λ,x,y)·AM1.5G(λ)·C·R_{A}(λ)·cos(x,y)

By weighting and averaging EQEᵣₑₐᵣ(λ,x,y) with the cos(x,y), an angle independent EQE(EQEᵣₑₐᵣ(λ)) that contains the cosine intensity distribution of the diffused light can be obtained:

$${EQE}_{rear} ( λ ) = \frac{1}{2 {\sum }_{X = 0}^{90} cos ( x )} ( {\sum }_{x = 0}^{90} EQE ( λ , x ) cos ( x ) + {\sum }_{x = 0}^{90} EQE ( λ , y ) cos ( y ) )$$

Therefore, the expression for the total short circuit current density (jₜₒₜₐₗ) can be expressed as:

jₜₒₜₐₗ=∫_{λ}_{ₘᵢₙ}^{λ}^{ₘₐₓ}(AM1.5G(λ)·EQE_{front}(λ)+AM1.5G(λ)·C·R_{A}(λ)EQEᵣₑₐᵣ(λ))·dλ

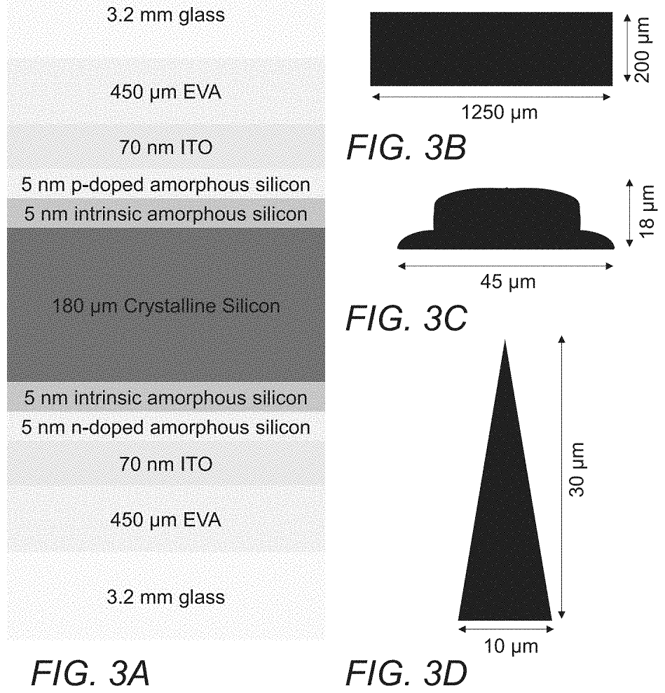

Computational optical simulations can be performed in order to determine the external quantum efficiency (“EQE”) of bifacial silicon heterojunction solar modules for front and rear side illumination in accordance with various embodiments of the invention. In one particular simulation, a thickness of 180 μm was chosen for the monocrystalline silicon absorber, which is passivated by 5 nm intrinsic amorphous silicon. Front and rear of the crystalline silicon exhibit random texture. The front side selective contact is a 5 nm p-doped amorphous silicon layer, and the rear side selective contact is 5 nm n-doped amorphous silicon. Front and rear both have a 70 nm indium tin oxide (“ITO”) layer for achieving good lateral charge transport and antireflection properties. In many embodiments, ˜70 nm ITO can provide optimal antireflection properties in multiple spectral albedo scenarios. On front and rear, an encapsulation made of a 450 μm layer of ethylene vinyl acetate (“EVA”) and 3.2 mm glass with antireflection coating was assumed. FIG. 3A conceptually illustrates a schematic of the layer structure in accordance with an embodiment of the invention. Simulations of modules without any metal contacts were performed in order to have a reference for determining shading losses and light trapping. As reference for a state-of-the-art optimal screen-printed contact, the shape of double screen-printed contact fingers was used. These contact fingers were assumed to be 18 μm height by 45 μm wide and feature rounded shapes as commonly found in state-of-the-art optimal screen-printed contact devices (shown in FIG. 3C). Metal coverage of reference contact fingers was assumed to be 3.4% at the front and 4.8% at the rear. Three busbars (1.25 mm wide and 200 μm high) with a total coverage of 2.4% were used for the front and rear sides (shown in FIG. 3B). ETC grids can also be simulated assuming no, one, two, or three busbars (with the same properties as the reference). ETCs were assumed to have triangular cross-section metal lines with 10 μm width and 30 μm height (shown in FIG. 3D). The module size was assumed to be a single cell standard module with dimensions of 156 cm×156 cm. The front and rear coverage was varied between 5% and 50% to determine the optimal configuration. Discussions on the impact of different designs and amount of coverage can be found in further detail in the sections below.

In order to obtain an accurate representation of the thin film optical properties of the solar cell while also simulating micro and millimeter scale features with reasonable computational capacity, a two-step simulation method can be used. First, the reflection, transmission, and parasitic absorption at the interface between EVA and the solar cell can be performed via thin film simulations performed with an optics simulation program (e.g., PVLighthouse's OPAL 2). The optical properties at the interface can be obtained for angles of incidence between 0° and 89° to the surface normal for the case of front and rear illumination. N-doped a-Si exhibits higher parasitic absorption than p-doped silicon, and therefore, front and rear were simulated individually. These results can be fed into a ray optical simulation model (e.g., using LightTools). The full module includes a 180 μm absorber with the bulk optical properties of crystalline silicon while the surface on the front and back side are defined by the OPAL 2 results. The EVA and glass encapsulation, busbars, screen-printed fingers, and ETCs can be explicitly added to the LightTools model. The approach described above can also accurately account for total internal reflection at the glass/air interface of the device. In many if not all cases, the total reflection and the absorption in every single layer can be simulated. In particular, the approach can be used to obtain the absorption within the crystalline silicon and to account for parasitic absorption within the other layers. In the sections below, front and rear illumination are considered separately and the overall result are summarized. In the following sections, an internal quantum efficiency of one over the whole wavelength regime is assumed, in which case the absorption within the crystalline silicon corresponds to the external quantum efficiency of the solar module.

### Front Side Illumination

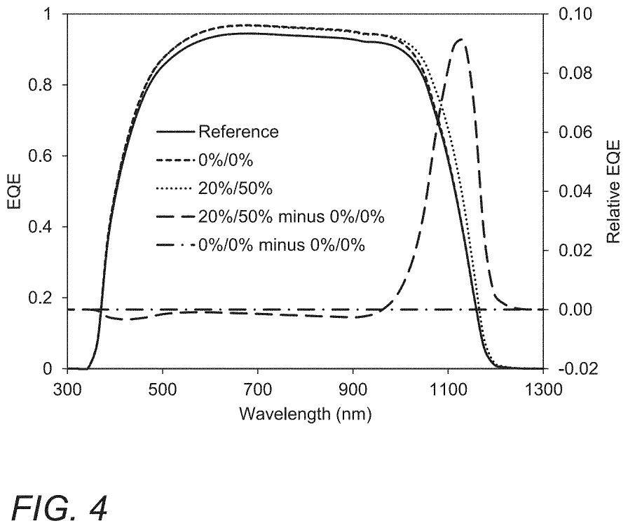

The effect of different contact layouts on the absorption within the crystalline silicon can be modeled in many different ways. To start, the effects can be modeled assuming only illumination from the front side. FIG. 4 shows a graph of the corresponding EQE depending on wavelength for several module configurations in accordance with various embodiments of the invention. As shown, the EQE for a module with the reference double screen printed fingers (black curve), for a module without any metallization (black disrupted curve), and for a module with 20% ETC coverage on the front and 50% ETC coverage on the rear (round dotted curve) are plotted against wavelength. The three curves refer to the left y-axis. In all cases, shading from busbars was neglected. The reference fingers lower the EQE while ETCs perform similarly to a module without metallization for wavelengths shorter than 1000 nm. For longer wavelengths, the EQE with ETCs even exceeds the EQE of a module without metallization. This effect results from light trapping. Light that was not absorbed in the first path can experience a chance (related to the rear ETC coverage) to be reflected at the bottom of the rear ETCs. In order to make clearly visible the difference between ETCs and no metallization, the EQE with ETCs was subtracted by the EQE without ETCs (long dashed curve in FIG. 4). As a reference, the black dashed curve shows the subtraction of the EQE without metallization by itself. Both curves refer to the right y-axis. It can be seen that ETCs yield a slightly lower EQE in the shorter wavelength regime compared no metallization. This result can be due to parasitic absorption within the silver that makes up the ETCs. However, the EQE is significantly increased in the longer wavelength regime due to light trapping, which can more than compensate for the losses in the shorter wavelength regime.

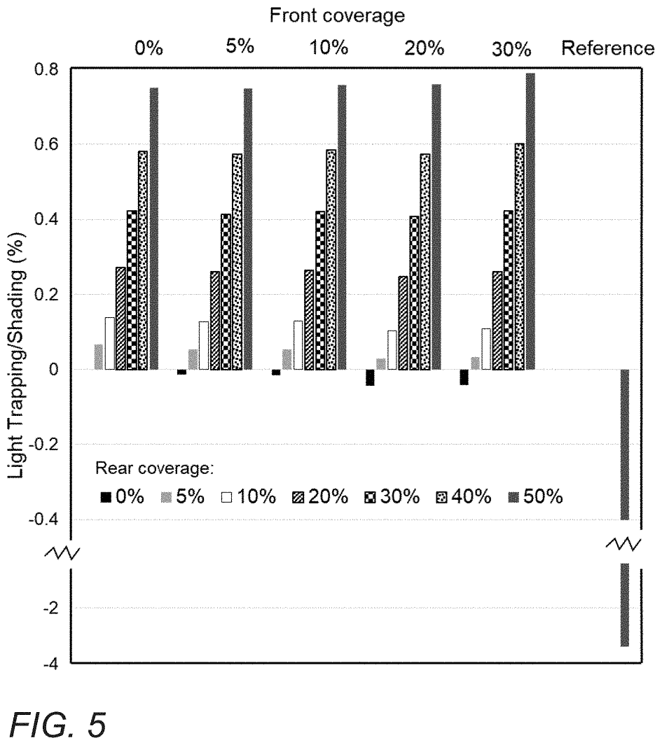

Many embodiments of the invention are directed towards different ETC grid designs that coverage specific portions of the active area of the solar cell. Multiple front and rear ETC coverage scenarios are conceptually illustrated in FIG. 5. FIG. 5 shows a chart of the light trapping and shading loss (without busbars) of the reference grid and ETCs with different front and rear coverage displayed as the change in short current density compared to a bifacial module without metallization. The EQE was weighed with the AM 1.5G spectrum in order to obtain the short circuit current density (front), as described in the sections above. In FIG. 5, all different configurations were compared to the case without any metallization, and the change in percentage of the j_{front} is shown. Negative values mean losses due to shading while positive values can be attributed to light trapping. As shown, the reference with screen-printed fingers loses 2.3% j_{front} from shading. For the ETCs, losses increase for increased front coverage if the rear is not covered with metal. However, the losses do not exceed 0.1%, which corresponds to an effective transparency of >99.9%. With increased rear side coverage, the light trapping increases and j_{front} exceeds the no metallization case by up to 0.79%. It can be seen that for increased rear coverage, increased front coverage can contribute to the light trapping as well. With increased rear coverage, the chances increase that long wavelength photons undergo a second pass (as depicted by the solid arrow in FIG. 1). Only second path photons experience a light trapping effect from the front side coverage. Therefore, the light trapping on the front can increase the higher the light trapping on the rear. Busbar losses are neglected in FIG. 5 in order to focus on the finger and ETC properties. Each added busbar can contribute another ˜0.8% shading loss. In the reference cell with three busbars, this can add up to ˜2.4% additional shading. As can readily be apparent, ETCs configurations within solar modules can vary with respect to a number of different things, including but not limited to the number of busbars. By reducing the number of busbars, additional gain in effective transparency can be achieved. In a number of embodiments, the solar modules include ETCs with only one busbar.

### Rear Side Illumination

In addition to front side illumination, the optical performance of the reference finger grid and ETCs when exposed to rear side illumination can be compared. Lambertian light scattering of sunlight at the surroundings and randomized light incident on the rear can be assumed. As the light is incident from all angles, the angle dependent EQE for all different front and rear side coverages can first be determined. The same optical simulation as described above can be performed, and the angle of incidence can be varied between 0° and 89° to the surface normal. The angle can be varied along the x-axis, which is parallel to the finger grid lines, and along the y-axis, which is perpendicular to the finger grid lines. As described in the sections above, the angle dependent EQE should be weighted with a cosine factor.

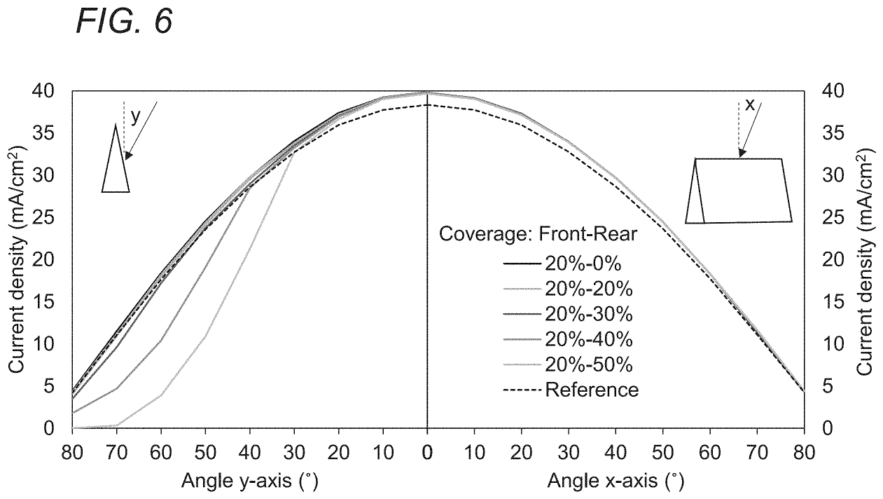

FIG. 6 conceptually illustrates the angle dependent rear side EQE weighted with a cosine factor for the reference double screen-printed metallization and for ETCs with 20% coverage on the front and varying coverage on the rear in accordance with various embodiments of the invention. As shown, the left side of the graph shows the y-axis and the right side shows the x-axis. Normal incidence (0°) is in the center. Note, that the light is incident from the rear, and the rear coverage is varied between 0% and 50% while the front coverage is kept constant. Furthermore, the rear uses n-doped amorphous silicon, and therefore, light incident on the rear can experience slightly higher parasitic absorption within the amorphous layer than light incident on the front. For 0°, a similar result as in FIG. 5 was obtained—ETC grids perform optically similar to no metallization while the reference grid inhibits 2.9% loss. The higher loss compared to the front can result from the higher metal coverage on the rear for the reference used. With increasing angle along the a-axis, the current density decreases due to a decrease in EQE and the cosine factor. The EQE decreases with increasing angle of incidence due to a less favorable behavior of the antireflection coating. Along the x-axis, ETCs outperform the reference case and the ETC coverage has minimal to no influence. For light incident from the y-axis, the current density depends on the ETC coverage. For steep angles, there is no dependence. However, for increasing angle, the current density experiences a cutoff for high ETC coverage. For high coverage and high incident angle, ETCs shade the active area, and light incident on the metal lines is likely to be reflected to a neighboring metal line instead of the active area. Therefore, the cutoff angle decreases with increasing coverage. For 20% coverage the current density stays above the reference case, for 30% coverage it crosses the reference case at 50°, for 40% coverage at 40°, and for 50% coverage at 30°.

### Optimal Front and Rear Configuration

In the sections above, the effects of different ETC front and rear coverage for either front or rear illumination were examined. For front illumination, higher rear coverage can lead to increased EQE due to light trapping. However, as shown in FIG. 6, increased rear coverage can lead to a cutoff in current generation for light that is incident under an oblique angle parallel or near parallel to the y-axis. Given a goal of obtaining the highest current generation overall (i.e., maximize the sum of the current generated from front and rear illumination), the equation introduced in the sections above can be used to derive the optimal configuration (assuming mostly direct illumination under normal incidence from the front and diffused light from the rear side). First, jₜₒₜₐₗ can be calculated by using the EQE results obtained using the methods and equations described in the sections above. For the calculation, a spectral independent albedo (R_{A}(λ)=constant) was assumed and was merged with the constant C. In this case, front side and rear side illumination experience the same wavelength dependence. Therefore, the rear side illumination can be expressed as a fraction of the front side illumination, which is dependent on the albedo and the geometric factors. The total current density jₜₒₜₐₗ can be calculated and compared to the case of a monofacial solar module with the reference screen-printed contact fingers. Furthermore, the number of busbars can be reduced down to one. In many case, the number of busbars can be reduced down to one if a front ETC coverage of more than 14% is implemented.

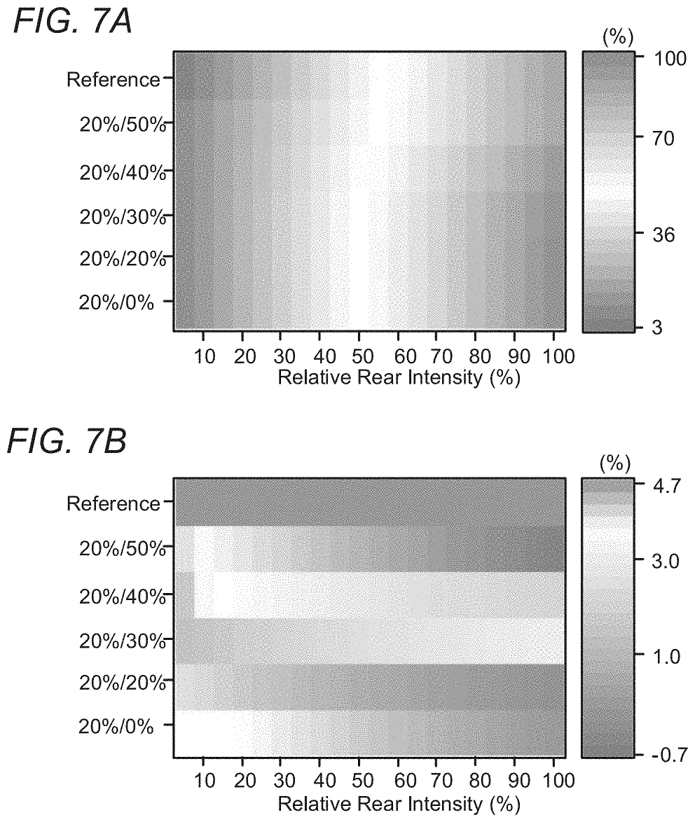

FIG. 7A conceptually illustrates the relative current density for different rear intensities and different contact configurations compared to a monofacial cell with the reference screen-printed contacts in accordance with various embodiments of the invention. As shown, the bifacial reference current exceeds the monofacial current for all cases although the module does not have a rear reflector and therefore, sub-optimal light trapping. This demonstrates why bifacial solar modules can generate more power whenever there is any possibility for light incident on the rear. Furthermore, it can be seen that the current density is increased when replacing the reference contact grid with ETCs. In order to investigate this effect more closely, the relative change in current density can be calculated when using ETCs compared to the reference bifacial module (shown in FIG. 7B). The reference screen-printed contacts are kept in the diagram as a guide to the eye and are constant zero. In almost all cases, ETCs exceed the reference. For ˜50% rear coverage, the current cutoff for light incident from the y-axis dominates and the overall current density is decreased. The lower the rear illumination intensity, the more beneficial it can be to use a higher ETC coverage.

### Coverage Scenarios for Bifacial Solar Cells Incorporating ETCs

Many embodiment of the invention are directed towards solar cells having higher than conventional coverage of the photoabsorbing surface(s). By increasing the ETC coverage, the emission angle can be restricted and photon recycling can be boosted, leading to reduced entropy losses and increased effective light concentration which will increase the open-circuit voltage and thereby conversion efficiency. Therefore, the ETCs offer the opportunity to increase the metal coverage to take advantage of these underlying processes without increasing the shading losses. When light is absorbed in the solar cell, it can be re-emitted through isotopic radiative emission. By increasing the coverage of ETCs on the solar cell front and/or rear side, the angular distribution of the isotropically re-emitted light can be restricted to increase the open-circuit voltage. In other words, restricting the emission angle can lead to reduced entropy losses on the open-circuit voltage and thereby directly boosting the efficiency. Additionally, by increasing the coverage of ETCs on solar cells, the light trapping is increased, which leads to increased photon recycling. The increased photon recycling can lead to increased effective light concentration in the solar cell, and thereby boosts the open-circuit voltage. The concept of photon recycling is known and an important mechanism to take into account when designing III-V (especially GaAs) solar cell devices.

Many embodiments of the invention are directed towards different ETC grid designs that coverage specific portions of the active area of the solar cell. Simulations and computations typically assume certain environmental conditions. However, configurations of different coverage can be advantageous over one another depending on the specific application and operating condition. For example, higher coverage can result in better trapping while lower coverage can be better for collecting scattered light. As a result, the ETC grid can be designed for specific applications and wavelength regimes. For example, as described above, FIG. 7B illustrates the light absorption for different rear illumination intensity for different contact configurations. For less than 15% relative rear illumination intensity, an optimum coverage can be achieved at ˜30% and can yield a relative current density increase of ˜4.4%. For a rear illumination intensity greater than 15%, a rear coverage of ˜20% can offer optimal conditions and can lead to a current density increase of 4.5-4.7%, depending on the rear illumination intensity. This result takes into account that the ETCs use two busbars less, which corresponds to a shading advantage of 1.6%.

As can readily be appreciated, the configuration of ETC girds, busbars, and coverage percentage can depend on the specific requirements of a given application. For example, different types of solar cells can have different optimal coverage percentage. Bifacial solar cells in accordance with various embodiments of the invention can include photoabsorbing surfaces that can be made of various materials including but not limited to: III-V material, GaAs, CdTe, GICS, perovskite, and silicon. Depending on the type of materials, different devices can have different optimal configurations. Additionally, as discussed above, operating conditions and environmental factors can play a huge role in determining optimal coverage. In many embodiments, a bifacial cell is implemented to have ETC coverage of higher than 10%. In further embodiments, the bifacial cell is configured to have a back ETC coverage that is higher than its front ETC coverage. In some embodiments, the bifacial cell is configured to have a front ETC coverage of ˜20% and a rear ETC coverage between 0% and 50%.

### Metal Grid Conductivity and Silver Usage

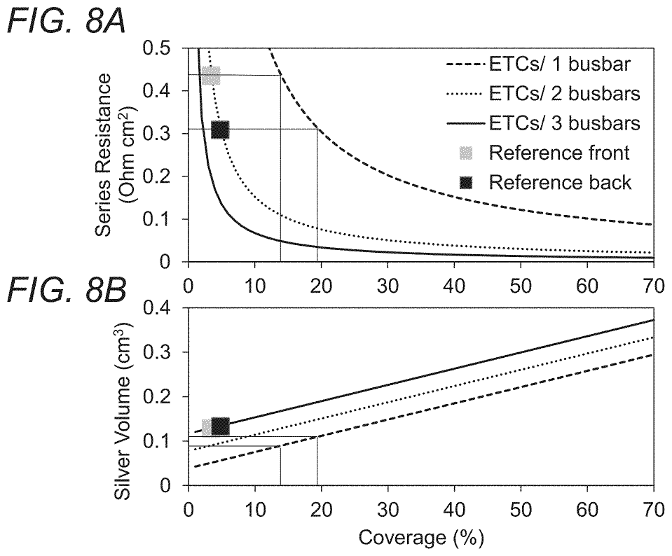

The sections above discuss the advantages in optical performance when replacing standard grid fingers with ETCs. However, in order to benefit from the increase in photon absorption, the grid resistance should not increase. Therefore, the grid resistance of the reference with standard fingers and three busbars as well as ETCs with different coverage and one, two, and three busbars can all be calculated to make such a determination. FIG. 8A shows a graph plotting the series resistance against varying coverages for different grid configurations in accordance with various embodiments of the invention. As shown, the series resistance results are presented for the reference (for front and rear grid represented by grey and black squares, respectively) and for ETCs with 1, 2, and 3 busbars (represented by dash, dotted, and solid line(s), respectively). An ink with conductivity of 4.5 μΩ cm and multiple busbar-ribbon connection pads were assumed. Use of a different ink would change the absolute series resistance values of the grids but should not alter the comparison between ETCs and the reference used as the series resistance scales linearly with the ink conductivity. A grid resistance of 3.3 Ωcm² for the reference front grid and 2.3 Ωcm² for the rear side grid were obtained. In FIG. 8A, it can be seen that if a coverage of >14% is used on the front side, only one busbar is necessary in order to achieve lower series resistance than the reference. The respective coverage for the rear side amounts to >20%. If two busbars can be removed compared to the reference, another additional 1.6% j_{sc} increase can be obtained compared to the cases presented in FIG. 5.

Furthermore, the silver ink usage for the different grid configurations are calculated and summarized in FIG. 8B. Again, results of the front and rear reference grids are shown as grey and black squares, respectively. The silver usage for grids with different ETC coverage is shown in black solid (three busbars), black dotted (two busbars) and black dashed curves (one busbar). It can be seen that with one busbar, the ETCs do not exceed the silver usage of the reference as long as the coverage is below 25%. Therefore, the above-described scenario demonstrates superior performance in terms of optics, series resistance, and ink consumption compared to conventional devices in the current field. To summarize, by replacing screen-printed contact fingers with effectively transparent contacts, significant enhancement of light absorption within bifacial solar cells can be achieved. The microscale triangular cross-sectional ETCs have the capability to redirect incoming light efficiently to the active area of the solar cell and allow for the mitigation of shading losses. Furthermore, embodiments containing close spacing of ETCs can lead to the trapping of long wavelength photons and, thereby, additional increase in light absorption. The close spacing can also allow for the reduction in the number of busbars implemented. In many embodiments, only one busbar is utilized. Through calculations and simulations, optical grid layouts for bifacial solar cells can be determined for specific operating conditions. In some embodiments, a grid layout is implemented to include one busbar and ˜20% ETC coverage on the front and one busbar and ˜20-30% ETC coverage on the rear. With this configuration, the total light absorption from the front and rear sides can be increased by ˜4.4-4.7%, depending on the relative rear intensity. At the same time, the series resistance of the contact grid and the ink usage can be maintained or even reduced. In several embodiments, the ink usage can be reduced by 15%. Furthermore, ETCs are compatible with the SmartWire technology, a cell connection process, which can decrease the optical losses of busbars and can become increasingly important for industrial solar cells.

### Embodiments Incorporating ETC Superstrates

In solar cell applications, a superstrate incorporating effectively transparent contacts (“ETCs”) can be implemented to boost solar cell power output. Superstrates and methods of manufacturing superstrates are discussed in further detail in U.S. application Ser. No. 16/192,704, entitled “Superstrates Incorporating Effectively Transparent Contacts and Related Methods of Manufacturing.” In conventional solar cells, metal contacts are typically required for charge extraction from solar cells. Traditional screen-printed metal contact grids typically cover up to ˜5% of the cell front surface, blocking sunlight from reaching the photovoltaic absorber below. These shading losses are among the largest causes of performance loss in most solar cells. For certain solar cells, another major optical loss mechanism emerges from the transparent conductive oxide (“TCO”) needed to provide low loss lateral charge transport. These TCOs can exhibit parasitic absorption that leads to significant loss in current density. Furthermore, in large-scale devices, the high photocurrents can require metal grid fingers in order to achieve low resistance. These metal fingers can lead to further optical losses due to geometric shading.

Superstrates containing ETCs (“ETC superstrates”) in accordance with various embodiments of the invention can be implemented to reduce optical losses by decreasing the thickness of the TCO and by reducing or eliminating shading losses of metal grid fingers. In many embodiments, the TCO layer thickness is less than 200 nm. In further embodiments, the TCO layer thickness is less than 100 nm. The superstrates can incorporate effectively transparent contacts (“ETCs”) that enable a significant reduction in the TCO thickness required for current extraction with a high fill factor. By reducing the thickness of the TCO layer in solar cells, the short circuit current density can be enhanced by more than 1 mA/cm² due to decreased parasitic absorption and optimized antireflection properties. However, in order to provide low-loss lateral charge transport, decreased TCO thickness requires the introduction of metal grid fingers. Effectively transparent contacts in accordance with various embodiments of the invention are microscale fingers capable of redirecting incoming light towards the active area of the solar cells. As such, the contacts can be placed closely together without introducing shading losses. In some embodiments, integrating ETCs in solar cell superstrates can lead to high conductivity (<5 Ω/sq sheet resistance). For some applications, such as in the case of perovskite solar cells, the absorption within the active layer can even exceed the absorption of cells without metal grids due to light trapping. As discussed above, ETCs in accordance with various embodiments of the invention can also be utilized to reduce shading losses. In many embodiments, the ETCs are triangular shaped, high-aspect-ratio silver gridlines. When sunlight impinges the ETC gridlines, the incident rays can be efficiently reflected towards the active area of the solar cell, rather than being reflected away and lost. Such techniques can substantially reduce and/or eliminate the shading loss problem and boosts the solar cell power output. In some embodiments, solar cell power output can be increased by ˜5%. In a number of embodiments, ETCs can achieve effective optical transparency of greater than 99% even at relatively dense grid spacing and over a wide range of angles of incidence. In many cases, the integration of ETCs can allow for a transparency of ˜99.9%.

Superstrates containing ETCs can be constructed in many different ways. In many embodiments, ETC superstrates include a transparent material with grooves, which can be infilled with reflective, conductive material(s) such as but not limited to silver and aluminum. In further embodiments, the grooves are triangular-shaped. In some embodiments, the ETC superstrate incorporates one or more transparent conductors on the side of the ETCs, such as but not limited to TCOs such as indium tin oxide (“ITO”), conductive polymers such as PEDOT:PSS, nanowire meshes such as silver nanowires. ETC superstrates can also incorporate transparent layers on the side opposite the ETCs, such as but not limited to glass layers and antireflective coatings The ETC superstrate can further incorporate other elements of benefit depending on the given application. For example, in solar cell applications, bus bars or tabbing pads can also be incorporated. Additionally, features to aid in attaching the ETC superstrate to the solar cell, such as but not limited to voids and indentations can be incorporated to provide clearance around bus bars or tabbing areas. ETC superstrates in accordance with various embodiments of the invention can be incorporated in many different applications. In many embodiments, the ETC superstrate can be applied to the front surface of a solar cell, such as but not limited to a crystalline Si and a III-V solar cell, by aligning the ETC gridlines with existing conventional gridline contacts on the solar cell. The composite can then be laminated or mechanically pressed. Some types of solar cells, such as amorphous heterojunction Si cells, may have a transparent conductive layer, such as an ITO layer, as the existing contact surface instead of conventional gridlines. In such cases, the ETC superstrate can be aligned using another point of reference. For example, the alignment can be performed by centering the ETC superstrate on the solar cell. In either case, the ETC superstrate can incorporate pre-treated surfaces, adhesives, and/or solder pastes to enable reliable mechanical attachment between the superstrate and the solar cell and/or to enable reliable electrical contact between the ETC gridlines and the solar cell's existing contacts during the lamination process. In the case of bifacial solar cells, which receive sunlight from either or both sides, ETC superstrates can, in the manner described above or any other method, be applied to either or both sides of the solar cell. As can readily be appreciated, the specific manner in incorporating ETC superstrates can depend on the specific application. For example, some embodiments include a solar cell with a CdTe layer that is deposited via vapor transport deposition (“VTD”), a process that occurs at temperatures around 400 C. In such embodiments, the ETC superstrate can be applied to the front surface of the solar cell, rather than as a platform onto which the CdTe is deposited via VTD since the ETC Superstrate cannot withstand the high temperatures at which the VTD process takes place.

In many embodiment, the ETC superstrate can be used as a platform onto which additional layers are deposited in order to fabricate the solar cell. For example, a perovskite solar cell can be fabricated on an ETC superstrate having an ITO-coated surface by sequentially depositing: a hole transport layer (“HTL”) such as but not limited to nickel oxide, a perovskite layer such as but not limited to methylammonium lead iodide, an electron transport layer (“ETL”) such as but not limited to PCBM, and a back contact electrode such as but not limited to silver. Such layers can be deposited by a variety of methods including but not limited to solution processing, spin coating, doctor blading, slot die casting, spraying, spray pyrolysis, vacuum deposition, evaporation, sputtering, and/or atomic layer deposition. Additionally, other types of thin-film solar cells can be deposited onto ETC superstrates, including but not limited to CdTe, CIGS, organic, dye-sensitized, and tandem combinations of thin-film solar cells. Further discussions of superstrates, computational simulations, and related methods of integration and fabrication in accordance with various embodiments of the invention can be found in the sections below.

The above described approach constitutes an effective and scalable way of enhancing the short-circuit current density in perovskite solar cells and incorporates materials that are widely used in the photovoltaic industry. Using such techniques, the area fraction devoted to macroscopic grid fingers and busbars can be further reduced on large-scale solar cells and modules as compared with conventional designs. Furthermore, ETC superstrates may find application in thin film tandem solar cell architectures as well as in other optoelectronic devices. In addition, ETC superstrates can be fabricated as thin and lightweight membranes that are particularly interesting for space, aviation, and mobile applications. In many embodiments, sol-gel ETC membranes with a thickness of 40-80 μm and a specific weight of 2.5±0.1 mg/cm² can be implemented. Compared to a standard glass substrate, such ETC membranes can be 1000 times lighter. As can readily be appreciated, any of a variety of different membrane materials, such as but not limited to PDMS and space resistant polymers, can be utilized.

### Doctrine of Equivalents

While the above description contains many specific embodiments of the invention, these should not be construed as limitations on the scope of the invention, but rather as an example of one embodiment thereof. It is therefore to be understood that the present invention may be practiced in ways other than specifically described, without departing from the scope and spirit of the present invention. Thus, embodiments of the present invention should be considered in all respects as illustrative and not restrictive. Accordingly, the scope of the invention should be determined not by the embodiments illustrated, but by the appended claims and their equivalents.

What is claimed is:

1. An optoelectronic device comprising:
a bifacial solar cell comprising a photoabsorbing material having first and second surfaces, wherein the first and second surfaces are configured to accept incoming external photons; and
a plurality of effectively transparent contacts disposed on the first and second surfaces, wherein:
the plurality of effectively transparent contacts comprises three-dimensional structures, each three-dimensional structure having at least one surface configured to redirect incident photons towards either the photoabsorbing material; and
the plurality of effectively transparent contacts covers at least 5% of the first surface from external photons.

2. The optoelectronic device of claim 1, wherein the photoabsorbing material comprises a material selected from the group consisting of: a III-V material, GaAs, CdTe, GICS, perovskite, and silicon.

3. The optoelectronic device of claim 1, further comprising a plurality of existing metallic contacts on the first surface, wherein at least a portion of the plurality of effectively transparent contacts are disposed on top of the existing metallic contacts.

4. The optoelectronic device of claim 1, wherein the plurality of effectively transparent contacts covers at least 10% of the first surface.

5. The optoelectronic device of claim 4, wherein the plurality of effectively transparent contacts covers about 20% of the first surface and less than 50% of the second surface.

6. The optoelectronic device of claim 1, wherein the plurality of effectively transparent contacts covers between 5% to 50% of the first photoabsorbing surface and between 5% to 50% of the second photoabsorbing surface.

7. The optoelectronic device of claim 1, wherein the plurality of effectively transparent contact covers the same percentage of the first surface and the second surface.

8. The optoelectronic device of claim 1, wherein the plurality of effectively transparent contact covers more of the first surface than the second surface.

9. The optoelectronic device of claim 1, wherein the first photoabsorbing surface contains only one busbar.

10. The optoelectronic device of claim 1, wherein the plurality of effectively transparent contacts comprises triangular contacts having aspect ratios of higher than 2:1.

11. The optoelectronic device of claim 1, wherein the triangular contacts are each approximately 10 micrometers wide and approximately 30 micrometers high.

12. The optoelectronic device of claim 1, wherein the plurality of effectively transparent contacts is configured to have an effective transparency of greater than 99%.

13. The optoelectronic device of claim 1, further comprising a polymer layer, wherein the polymer layer embeds the plurality of transparent contacts.

14. The optoelectronic device of claim 13, wherein the polymer layer comprises a material selected from the group consisting of: ethylene-vinyl acetate, polydimethylsiloxane, polyurethane, and polymethylmethacrylate.

15. The optoelectronic device of claim 1, wherein the polymer layer has a thickness of less than 500 μm.

16. The optoelectronic device of claim 13, further comprising a transparent conductive oxide layer having a thickness of less than 200 nm, wherein the transparent conductive oxide layer is in contact with the photoabsorbing layer.

17. The optoelectronic device of claim 16, wherein the transparent conductive oxide layer has a thickness of less than 100 nm.

18. The optoelectronic device of claim 16, wherein the transparent conductive oxide layer comprises a material selected from the group consisting of: indium tin oxide and fluorine doped tin oxide.

19. The optoelectronic device of claim 1, wherein at least one of the effectively transparent contact comprises silver nanoparticle ink.

20. The optoelectronic device of claim 1, wherein at least one of the effectively transparent contact comprises a triangular core in contact with at least two reflective surfaces.
